(19) United States
(12) Patent Application Publication
(10) Pub. No.: US 2008/0157270 A1
(43) Pub. Date: Jul. 3, 2008

(54) Metal to Metal Low-K Antifuse

(76) Inventors: Deok-kee Kim, Bedford Hills, NY (US); Anil K. Chinthakindi, Haymarket, VA (US); Son Van Nguyen, Yorktown Heights, NY (US); Kelly Malone, Poughkeepsie, NY (US); Byeongju Park, Plainview, NY (US)

Correspondence Address: FREDERICK W. GIBB, III;Gibb & Rahman, LLC, 2568-A RIVA ROAD, SUITE 304, ANNAPOLIS, MD, 21401, US

(21) Appl. No.: 11/618,757

(22) Filed: Dec. 30, 2006

(51) Int. Cl. H01L 29/00

(52) U.S. Cl. 257/530; 257/E23.149

(57) ABSTRACT

The embodiments of the invention generally relate to fuse and anti-fuse structures and include a copper conductor positioned within a substrate and a metal cap on the first conductor. A low-k dielectric is on the substrate and the metal cap. A tantalum nitride resistor is on the dielectric, and the resistor is positioned above the metal cap such that an antifuse element region of the dielectric is positioned between the resistor and the metal cap. The antifuse element region of the dielectric is adapted to change resistance values by application of a voltage difference between the resistor and the copper conductor/metal cap. The antifuse element region has a first higher resistance (more closely matching an insulator) before application of the voltage and a second lower resistance (more closely matching a conductor) after application of such voltage. In one embodiment herein the voltage can be supplemented by heating through application of voltage through the first conductor which helps change the resistance of the antifuse element region.

### BACKGROUND

1. Field of the Invention

The embodiments of the invention generally relate to fuse and anti-fuse structures used in write once read many (WORM) or one time programmable read only memories (OTPROM) and, more particularly, to an improved structure and method that changes, and detects the change in capacitance of a capacitor.

2. Description of the Related Art

Fuse devices are used in numerous applications including redundancy implementation in memory arrays, field programmable arrays, voltage trimming resistors/capacitors, RF circuit tuning, electronic chip id, usage tracking/diagnostic data logs, to remotely disable a device/car that is reported stolen, random access memories (ROM), etc.

Fuse devices are realized using many different technologies and materials. In U.S. Patent Publication 2005/0285224 (incorporated herein by reference), electromigration or agglomeration of silicide is disclosed, which is the electronic fuse (eFUSE) technology that is conventionally used today. As in U.S. Patent Publication 2006/0043595 (incorporated herein by reference), phase change materials such as GST (Ge₂Sb₂Te₅) or GeSbSi can be used in a fuse device as well as in non-volatile memories. The resistance change of copper-nickel-copper structure was used as a fuse device in U.S. Pat. No. 6,700,161 (incorporated herein by reference). Anti-fuse devices using gate oxide breakdown in a typical gate structure are known as well (U.S. Patent Publication 2006/0102982 (incorporated herein by reference)). Many other antifuse structures were reported before. In U.S. Patent Publication 2006/0097325 (incorporated herein by reference), CA tungsten plug—silicon dioxide—copper metal was used for an antifuse application. U.S. Patent Publication 2005/0023638A1 and U.S. Pat. No. 6,979,880 (incorporated herein by reference) disclose tungsten plug—dielectric (SRN (silicon rich nitride), lowK)-copper antifuses. U.S. Patent Publication 2003/0062596 (incorporated herein by reference) discloses a tungsten plug-amorphous carbon/amorphous carbon doped with hydrogen or fluorine, or amorphous silicon carbide—M1 (copper) antifuse. U.S. Patent Publication 2004/0087098 (incorporated herein by reference) discloses a TaN-high K—TaN capacitor which can be possibly used as an antifuse.

In the case of non-volatile memories and memories using phase change materials, new materials and/or processing steps compared to the standard complementary metal oxide semiconductor (CMOS) processing are required. In the case of electromigration fuses, typically a high programming voltage is required to electromigrate the silicide. When the standard gate structure or material is changed, it may require additional processing steps to form the silicided polysilicon structure. Further, in the case of antifuse devices using gate oxide breakdown in a typical gate structure, high voltage is typically required.

### SUMMARY

The embodiments of the invention generally relate to fuse and anti-fuse structures and include a copper conductor positioned within a substrate and a metal cap on the first conductor. A low-k dielectric is on the substrate and the metal cap. A tantalum nitride resistor is on the dielectric, and the resistor is positioned above the metal cap such that an antifuse element region of the dielectric is positioned between the resistor and the metal cap. Additional conductors identified as first and second contacts are connected to first and second ends of the resistor. The first contact and the second contact are above and outside opposite sides of the metal cap.

One feature herein is that the antifuse element region of the dielectric is adapted to change resistance values by application of a voltage difference between the resistor and the copper conductor/metal cap. The antifuse element region has a first higher resistance (more closely matching an insulator) before application of the voltage and a second lower resistance (more closely matching a conductor) after application of such voltage. In one embodiment herein the voltage can be supplemented by heating through application of voltage through the first conductor which helps change the resistance of the antifuse element region.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 comprises a schematic cross-sectional diagram of a programmable device according to embodiments herein;

FIG. 2 comprises a schematic top-view diagram of a programmable device according to embodiments herein; and

FIG. 3 comprises a schematic cross-sectional diagram of a programmable device according to embodiments herein.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

Disclosed herein is a copper—low k dielectric—TaN resistor antifuse. The inventive structure is formed using only conventional back end of line (BEOL) complementary metal oxide semiconductor (CMOS) processing. Therefore, the invention does not require any new equipment or materials. The first electrode compries the M1 copper metal and the standard low K dielectric in BEOL is used as a dielectric of the inventive antifuse. The TaN resistor (which is the second electrode) is usually formed in BEOL processing for resistor applications.

In one embodiment herein, the breakdown voltage is reduced. Thus, in a first embodiment, the programming is done by applying a high enough voltage differential between a K1 Cathode and the M1 electrode (or V1_{—}1 or V1_{—}2) in order to cause a breakdown of the SiCOH dielectric. In a second embodiment, the programming is done by applying a high enough voltage differential between the K1 Cathode and the M1 electrode (or V1_{—}1 or V1_{—}2) in order to cause a break down of SiCOH dielectric while heating the SiCOH by applying a voltage differential between V1_{—}1 and V1_{—}2 contacts. Alternatively, heating can be done through the TaN resistor (KI Cathode and KI Anode). By heating the SiCOH, the voltage required to break down the SiCOH is reduced.

Since a low K dielectric breaks down at a lower voltage compared to the regular gate oxide, the invention can be programmed at lower voltages, which reduces the chip area by reducing the area occupied by the programming transistors since smaller programming transistors can be used.

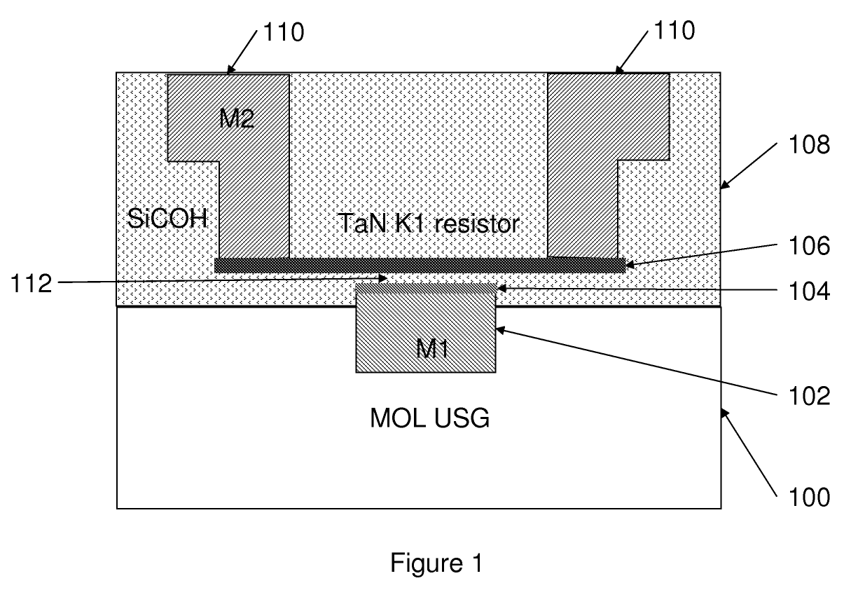

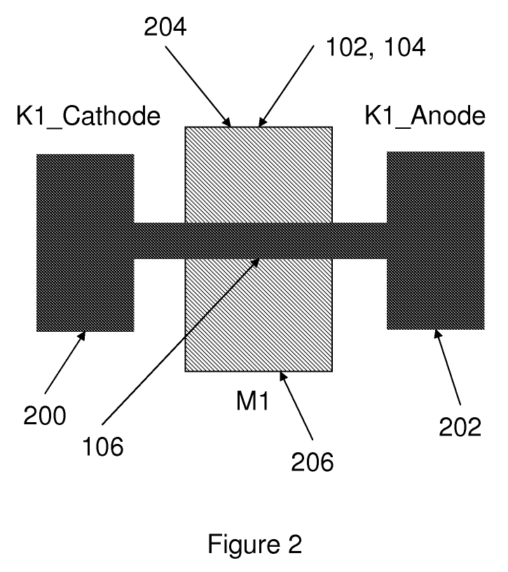

FIGS. 1 and 2 illustrate embodiments of the invention. More specifically, FIG. 1 illustrates a portion of a programmable structure such as a write once read many (WORM) or one time programmable read only memories (OTPROM). The structure includes a conductor 102 (e.g., copper) positioned within a substrate 100 and a metal cap 104 on the first conductor 102. A low-k dielectric 108 is on the substrate 100, the copper conductor 102, and the metal cap 104. A resistor (e.g., tantalum nitride) 106 is positioned in the dielectric 108. The resistor 106 is positioned above the metal cap 104 such that an antifuse element region 112 of the dielectric 108 is positioned between the resistor 106 and the metal cap 104. Additional conductors 110 (identified as first and second contacts, for convenience) are connected to opposite (first and second) ends of the resistor 106. The first and second contacts 110 are above and outside the opposite sides of the metal cap 104.

Processing for the inventive structure is easily integrated into conventional CMOS processing. More specifically, the standard CMOS processing is performed up to the middle of the line processing, where the isolation structures and the transistors with sources/drains and gates are formed. After that, standard contact formation processing is performed. MOL dielectrics such as BPSG (borophosphosilicate glass) or USG (undoped silicate glass) are deposited and planarized using CMP (chemical mechanical polishing). And then, contact etching is done and W (tungsten) contacts are deposited and planarized. M1 metal lines are formed by the standard copper damascene process. M1 low K dielectrics are deposited and patterned for M1 copper lines. Copper is electroplated after barrier layers (TaN & Ta) and seed layers are sputter-deposited, after which the structure is planarized by CMP. With the invention, a metal cap such as CoWP (Cobalt, Tungsten, Phosphorus), CoWB (Cobalt, Tungsten, Boron), or Cu—Al alloys is deposited after the M1 copper metal is recessed. Subsequent planarization removes the metal cap layer from other areas. The M1 copper with the metal cap is used as the first electrode in the inventive structure. Then a thin layer of low K dielectric (e.g., 100 Å of SiCOH) is deposited, and is used as the dielectric in the inventive antifuse. Then a TaN K1 resistor of (e.g., 400 Å, which can be used as the resistor as well as the second electrode in the inventive structure) is sputtered and patterned.

After this standard CMOS processing can be used to form contacts (V1) and the next level of metallization (M2 contacts). The low K dielectric (SiCOH) can be deposited and patterned for V1 and M2 formation. The barrier layers (TaN & Ta) and the copper seed layers are deposited, after which the copper is electroplated for V1 and M2 formation. The electroplated copper is planarized by CMP, which completes the V1 & M2 formation. After that, standard CMOS BEOL processing is performed to complete the transistors/devices.

One feature herein is that the antifuse element region 112 of the dielectric 108 is adapted to change resistance values by application of a voltage difference between the resistor 106 and the copper conductor/metal cap 104. The antifuse element region 112 has a first higher resistance (more closely matching an insulator) before application of the voltage and a second lower resistance (more closely matching a conductor) after application of such voltage. In one embodiment herein the voltage can be supplemented by heating through application of voltage through the first conductor 102 which helps change the antifuse element region into a conductor. More specifically, the first conductor 102 can generate heat when a voltage difference is generated between one end 204 and an opposite end 206 of the first conductor 102. Alternatively, heat can be generated by application of a voltage difference between one end 200 of the resistor 106 and the other end 202 of the resistor 106.

Thus, the top down schematic shown in FIG. 2, illustrates how the antifuse is programmed and sensed. Fuse programming is done by applying a high enough voltage between K1 Cathode and M1 (or V1 (206)) in order to cause the breakdown of the SiCOH dielectric. It is well-known that the breakdown voltage of the SiCOH is lower compared to SiO₂. Hence, a lower programming voltage can be used, which will reduce the chip area since smaller programming transistors can be used for the invention compared to the conventional silicon dioxide antifuse.

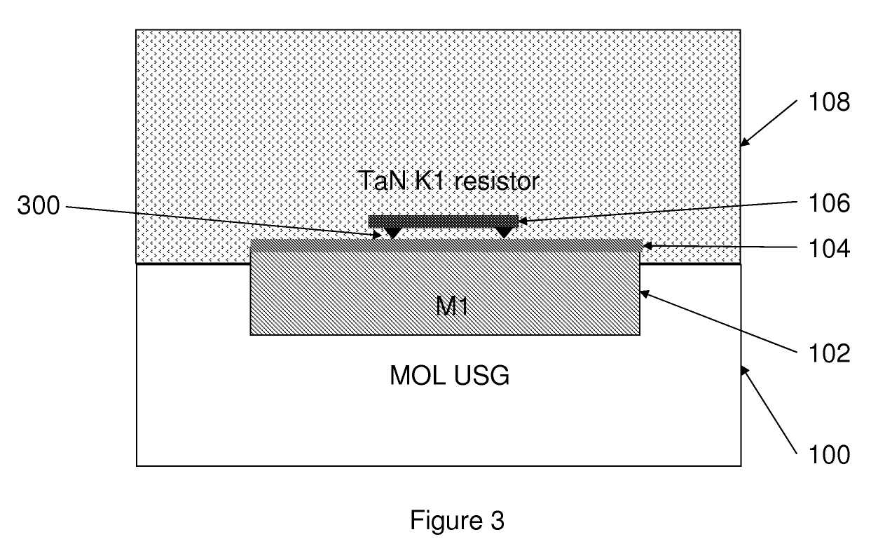

In one example, the breakdown field for one low-k dielectric is around 7-8 MV/cm, while the breakdown voltage for SiO₂ is around 10-12 MV/cm. The invention (antifuse using low K dielectric) breaks down easier compared to the conventional SiO₂ antifuse. Furthermore, during the etching of TaN resistor (which is the second electrode in this case), micro trenches are formed at the sides of the TaN resistor. Micro trenching (as indicated by the triangles 300 below the resistor 106 in FIG. 3 tends to cause the dielectric breakdown easier, which lowers the programming voltage even further and reduces the chip area significantly since smaller programming transistors can be used.

Sensing is done by measuring the resistance between the K1 Cathode 200 and the M1 electrode 102 (or V1 (206)) before and after programming. When the antifuse is intact, the resistance between the K1 Cathode 200 and the M1 electrode 102 (or V1 (206)) is high. When the antifuse is programmed, the resistance between the K1 Cathode 200 and the M1 electrode 102 (or V1 (206)) is low.

FIG. 2 also shows the schematic of the second embodiment. In the second embodiment, the programming is done by applying a high enough voltage differential between between the K1 Cathode 200 and the M1 electrode 102 (or V1_{—}1 (206) or V1_{—}2 (204)) in order to cause a break down of SiCOH dielectric while heating SiCOH 112 by applying a voltage differential between V1_{—}1 (206) and V1_{—}2 (204) to cause the electrode 102 to heat up. Alternatively, the heating can be done by applying a voltage difference through the TaN resistor 106 (K1 Cathode 200 and K1 Anode 202) to cause the resistor 106 to heat up. By heating the SiCOH using the resistor 106 or the electrode 102, the voltage required to break down the SiCOH is reduced, which reduces the chip area by requiring a smaller programming transistor.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. An antifuse structure comprising:
a substrate;
a first conductor positioned within said substrate;
a dielectric on said substrate;
a resistor on said dielectric, wherein said resistor is positioned above said first conductor such that an antifuse element region of said dielectric is positioned between said resistor and said first conductor;
a first contact connected to a first end of said resistor; and
a second contact connected to a second end of said resistor,
wherein said antifuse element region of said dielectric is adapted to change resistance values by application of a voltage difference between said resistor and said first conductor.

2. The structure according to claim 1, wherein said antifuse element region comprises an insulator before application of said voltage difference.

3. The structure according to claim 1, wherein said dielectric comprises a low-k dielectric.

4. An antifuse structure comprising:
a substrate;
a first conductor positioned within said substrate;
a metal cap on said first conductor;
a dielectric on said substrate and said metal cap;
a resistor on said dielectric, wherein said resistor is positioned above said metal cap such that an antifuse element region of said dielectric is positioned between said resistor and said metal cap;
a first contact connected to a first end of said resistor; and
a second contact connected to a second end of said resistor,
wherein said antifuse element region of said dielectric is adapted to change resistance values by application of a voltage difference between said resistor and said metal cap and by heating through application of voltage through said first conductor.

5. The structure according to claim 4, wherein said antifuse element region comprises an insulator before application of said voltage difference.

6. The structure according to claim 4, wherein said dielectric comprises a low-k dielectric.
